(19) United States
(12) Patent Application Publication
(10) Pub. No.: US 2013/0033339 A1
(43) Pub. Date: Feb. 7, 2013

(54) BIFURCATION-BASED ACOUSTIC SWITCH AND RECTIFIER

(71) Applicants: Nicholas BOECHLER, CULPEPER, VA (US); Georgios THEOCHARIS, LE MANS (FR); Chiara DARAIO, PASADENA, CA (US)

(72) Inventors: Nicholas BOECHLER, CULPEPER, VA (US); Georgios THEOCHARIS, LE MANS (FR); Chiara DARAIO, PASADENA, CA (US)

(21) Appl. No.: 13/552,042

(22) Filed: Jul. 18, 2012

Related U.S. Application Data
(60) Provisional application No. 61/514,352, filed on Aug. 2, 2011.

(51) Int. Cl. H03H 9/54

(52) U.S. Cl. 333/187

(57) ABSTRACT

A tunable frequency acoustic rectifier that is a granular crystal composed of a statically compressed one-dimensional array of particles in contact, containing a light mass defect near a boundary. The tunable frequency acoustic rectifier is nonlinear and contains tunable pass and stop bands in their dispersion relation. Vibrations at selected frequencies applied to the granular crystal from the side near the defect will cause the system to bifurcate at a critical input amplitude and subsequently jump to quasiperiodic and chaotic states with broadband frequency content. Some of this frequency content lies within the pass bands and will propagate through the crystal. Vibrations at the same frequencies applied to the other side of the granular crystal will not bifurcate, and little energy is transmitted.

### CROSS-REFERENCE TO RELATED APPLICATIONS

The present application is related to and claims the benefit of the following copending and commonly assigned U.S. Patent Application: U.S. Patent Application No. 61/514,352, titled “Bifurcation-based Acoustic Switch and Rectifier,” filed on Aug. 2, 2011; the entire contents of this application are incorporated herein by reference.

### STATEMENT REGARDING FEDERALLY SPONSORED RESEARCH OR DEVELOPMENT

This invention was made with government support under CMMI-0844540; CMMI-0969541; DMR-0520565 awarded by the National Science Foundation and under N00014-10-1-0718 awarded by the Office of Naval Research. The government has certain rights in the invention.

### BACKGROUND

1. Field

The present disclosure relates to systems and methods for controlling the propagation of acoustic waves and mechanical vibrations. More in particular, the present disclosure describes apparatus, systems and methods for tunable frequency acoustic switches and rectifiers.

2. Description of Related Art

Switches and rectification devices are fundamental components used for controlling the flow of energy in numerous applications. Thermal and acoustic rectifiers have been proposed for use in biomedical ultrasound applications, thermal computers, energy saving and harvesting materials, and direction-dependent insulating materials. In all these systems, the transition between transmission states is smooth with increasing signal amplitudes. This limits their effectiveness as switching and logic devices, and reduces their sensitivity to external conditions as sensors. Existing acoustic or thermal rectifiers generally do not have a sharp transition between transmitting and non-transmitting states. Therefore, there exists a need in the art for acoustic rectifiers that provide a sharper transition between transmitting and non-transmitting states to improve the effectiveness of such rectifiers.

### SUMMARY

Described herein are devices, apparatus, methods, arrays, and systems that comprise tunable frequency acoustic switches and rectifiers. In such devices, apparatus, methods, arrays, and systems, acoustic waves (and mechanical vibrations) propagate in one direction, but are nearly completely blocked in the other direction. There also may be a sharp transition between transmitting and non-transmitting states, which is sensitive to small changes in input acoustic signals and which may find use, for example, in acoustic wave sensors. New types of “acoustic logic” devices may also utilize the sharp transition between transmitting and non-transmitting states.

No existing acoustic or thermal rectifier has shown a sharp transition between transmitting and non-transmitting states. The detailed description below describes a granular crystal being used as a rectifier for continuous acoustic waves. As described below, the resulting rectifier shows a tunable response over a broad range of frequencies, generally not achievable by other devices known in the art.

The detailed description below describes a novel mechanism based on nonlinear bifurcations to enable the sharp transition between transmitting and non-transmitting states. This bifurcation mechanism allows for several improvements over existing devices and the addition of new types of functionality. By operating the device near the transition point, any small perturbations to the input will cause the device to switch transmission states, which allows the device also to function as an ultra-sensitive acoustic sensor. Due to the two separate (binary) transmission states, when coupled together, these devices can also be used to create “acoustic logic” devices. Furthermore, because of the frequency converting nature of the quasiperiodic and chaotic transmitting state, the novel mechanism may also be used in signal scrambling applications or in applications where frequency down-conversion increases the overall system efficiency.

### BRIEF DESCRIPTION OF THE SEVERAL VIEWS OF THE DRAWINGS

FIG. 1A depicts a structure comprising a granular crystal with 19 spherical particles, an actuator, and an applied static load in a reverse configuration.

FIG. 1B shows a conceptual diagram of the rectification mechanism provided by the system shown in FIG. 1A.

FIG. 1C depicts a structure comprising a granular crystal with 19 spherical particles, an actuator, and an applied static load in a forward configuration.

FIG. 1D shows a conceptual diagram of the rectification mechanism provided by the system shown in FIG. 1C.

FIG. 2 is a graph showing the maximum dynamic force as a function of driving amplitude.

FIG. 3A is a graph of measured dynamic force at a point four particles from the actuator in the forward configuration structure shown in FIG. 1C with the driving amplitude set to 0.43 μm.

FIG. 3B is a graph of the Power Spectral Density of the measured force-time history for sensors located four particles and nineteen particles from the actuator in the forward configuration structure shown in FIG. 1C with the driving amplitude set to 0.43 μm.

FIG. 3C is a graph of measured dynamic force at a point four particles from the actuator in the forward configuration structure shown in FIG. 1C with the driving amplitude set to 0.60 μm.

FIG. 3D is a graph of the Power Spectral Density of the measured force-time history for sensors located four particles and nineteen particles from the actuator in the forward configuration structure shown in FIG. 1C with the driving amplitude set to 0.60 μm.

FIG. 3E is a graph of measured dynamic force at a point four particles from the actuator in the forward configuration structure shown in FIG. 1C with the driving amplitude set to 0.85 μm.

FIG. 3F is a graph of the Power Spectral Density of the measured force-time history for sensors located four particles and nineteen particles from the actuator in the forward configuration structure shown in FIG. 1C with the driving amplitude set to 0.85 μm.

FIG. 3G is a graph of measured force-time history at a point four particles from the actuator in the reverse configuration structure shown in FIG. 1A with the driving amplitude set to 0.85 μm.

FIG. 3H is a graph of the Power Spectral Density of the measured force-time history for sensors located four particles and nineteen particles from the actuator in the reverse configuration structure shown in FIG. 1A with the driving amplitude set to 0.85 μm.

FIG. 4A is a graph of the experimentally measured power as a function of driving amplitude in the structures depicted in FIGS. 1A and 1C.

FIG. 4B is a graph of the numerically calculated average power as a function of driving amplitude in the structures depicted in FIGS. 1A and 1C.

FIG. 4C is a graph of numerical time-averaged energy density as a function of position for the reverse configuration depicted in FIG. 1A.

FIG. 4D is a graph of numerical time-averaged energy density as a function of position for the forward configuration depicted in FIG. 1C.

FIG. 5A is a graph of the experimentally measured PSD transfer function of the reverse configuration shown in FIG. 1A.

FIG. 5B shows the experimentally measured PSD transfer function of the forward configuration shown in FIG. 1C.

FIG. 6A is a graph of the Floquet spectrum of the periodic solution corresponding to the forward configuration shown in FIG. 1C.

FIG. 6B shows the time evolution of the unstable periodic solution of FIG. 6A.

FIG. 6C shows the Power Spectral Density of the time region from 100 ms to 200 ms of FIG. 6B.

FIGS. 7A-7D show the Power Spectral Density of numerically calculated force-time histories at various driving amplitudes for the fourth particle from the actuator in the forward configuration depicted in FIG. 1C.

FIG. 8A shows an AND gate obtained from a tunable rectifier structure having a granular crystal with a defect particle.

FIG. 8B shows an OR gate obtained from tunable rectifier structures, each structure having a granular crystal with a defect particle.

### DETAILED DESCRIPTION

The exemplary embodiments according to the present invention described in this disclosure provide devices, apparatus, methods, arrays and systems that provide for acoustic waves (and mechanical vibrations) that propagate in one direction, but are nearly completely blocked in the other direction. The exemplary embodiments may also exhibit a sharp transition between transmitting and non-transmitting states, which may be sensitive to small changes in input acoustic signals.

Periodicity in materials has proven useful for the control of wave propagation in electronic and photonic, mechanical, acoustic, and optomechanical systems. The presence of nonlinearity in periodic dynamical systems makes available an array of useful phenomena (including localization, breathers, bifurcation, and chaos). The interplay of periodicity, nonlinearity, and asymmetry in granular crystals results in novel types of switching and rectification devices according to embodiments of the present invention.

An embodiment of the present invention comprises a rectifier that is a granular crystal, composed of a statically compressed one-dimensional array of particles in contact, containing a light mass defect near a boundary. Systems using such a granular crystal are nonlinear and contain tunable pass and stop bands in their dispersion relation. Vibrations at selected frequencies applied to the granular crystal from the side near the defect will cause the system to bifurcate at a critical input amplitude and subsequently jump to quasiperiodic and chaotic states with broadband frequency content. Some of this frequency content lies within the pass bands and will propagate through the crystal. Vibrations at the same frequencies applied to the other side of the granular crystal will not bifurcate, and little energy is transmitted.

Granular crystals are densely packed arrays of elastic particles that interact nonlinearly via Hertzian contacts. These systems are tunable from near-linear to strongly nonlinear dynamical regimes, by changing the ratio of static to dynamic inter-particle displacements. Granular crystals have allowed the exploration of fundamental phenomena, and have been applied in engineering devices (see, for example, Spadoni, A. & Daraio, C., “Generation and control of sound bullets with a nonlinear acoustic lens,” Proc. Natl. Acad. Sci. USA. 107, 7230 (2010) and Hong, J., “Universal power-law decay of the impulse energy in granular protectors,” Phys. Rev. Lett. 94, 108001 (2005)).

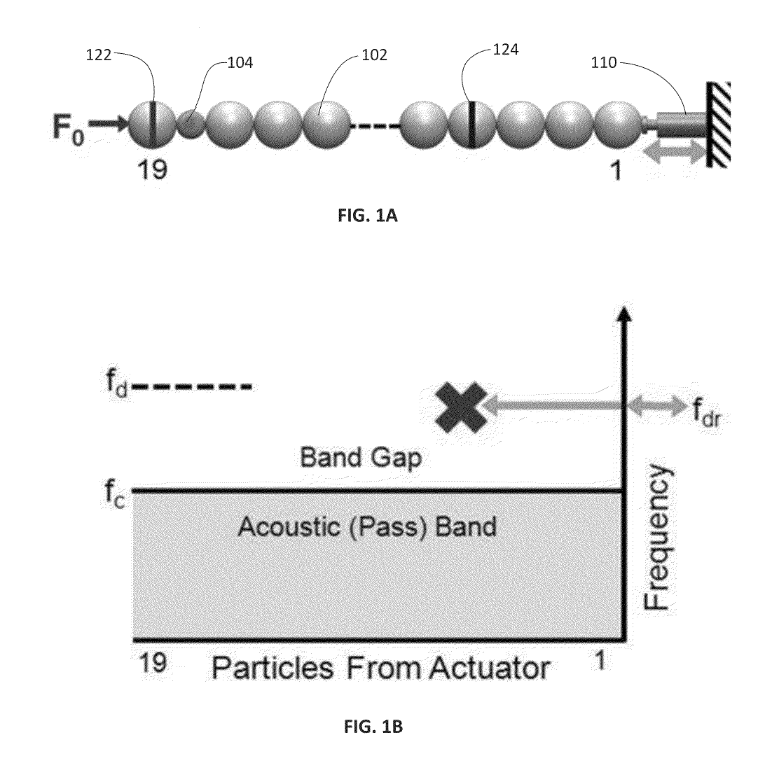

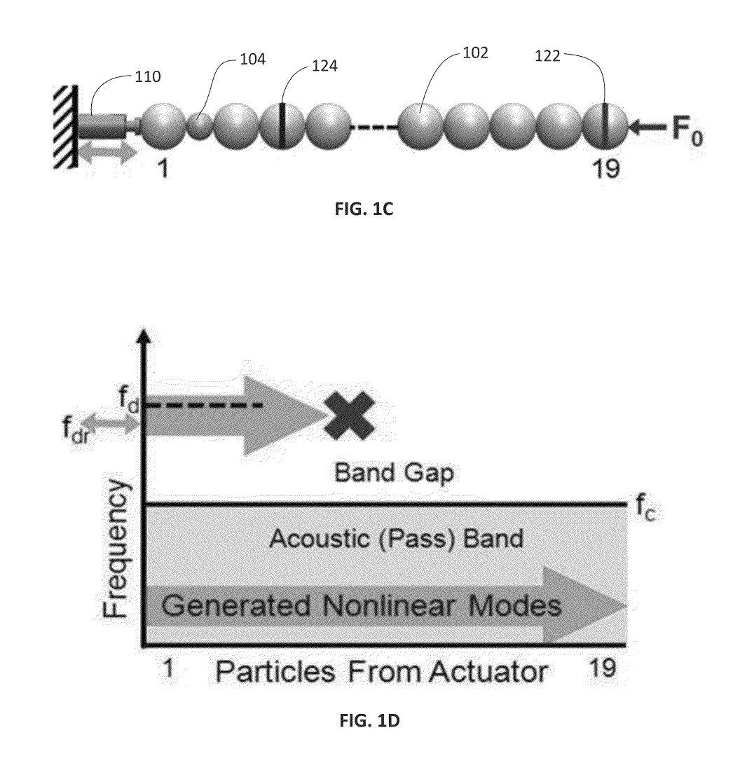

An exemplary granular crystal may comprise a statically compressed 1D array of stainless steel spherical particles. FIGS. 1A and 1C depict a granular crystal configuration having a total of N=19 stainless steel particles with 18 non-defect particles 102 and 1 defect particle 104. For investigation purposes, the non-defect particles 102 had a measured radius R=9.53 mm and mass M=28.84 g and the defect particle 104 had measured radius r=5.56 mm and mass m=5.73 g. Longitudinal dynamic displacements are applied with a piezoelectric actuator 110 and the crystal is compressed mechanically as described in additional detail below. FIG. 1A depicts a configuration with the actuator 110 on the right, i.e., a “reverse configuration.” FIG. 1C depicts a configuration with the actuator 110 on the left, i.e., a “forward configuration.” In both configurations shown in FIGS. 1A and 1C, a dynamic force-time history is measured with in-situ piezoelectric sensors 122, 124. In the configurations shown in FIGS. 1A and 1C, one sensor 124 is placed four sites from the actuator 110 and the other sensor 122 is placed at the other end.

A statically compressed homogeneous granular crystal acts as a low pass frequency filter. When the particles are identical, the crystal supports one band of propagating frequencies called the acoustic band, extending from frequency f=0 to the upper cutoff frequency f_{c}. Vibrations with frequencies f>f_{c} lie in a band gap and cannot propagate through the crystal. The presence of a light-mass defect breaks the periodicity of the crystal, and induces an exponentially localized mode with frequency f_{d}>f_{c}. Frequencies f_{c} and f_{d} depend on the geometric and material properties of the system and are proportionally tunable with static load.

Conceptual diagrams of the rectification provided by the structures shown in FIGS. 1A and 1C are shown in FIGS. 1B and 1D. One end of the statically compressed 1D array stainless steel spherical particles shown in FIGS. 1A and 1C is driven harmonically. The frequency of the driver f_{dr} is fixed at a frequency in the gap, below f_{d}, and the driving amplitude δ is increased. In the reverse configuration shown in FIG. 1A where the crystal is driven far from the defect in the crystal, the energy provided by the actuator does not propagate through the crystal because of the band gap, i.e., the band gap filters out frequencies in the gap. FIG. 1B illustrates that frequencies below f_{c} will propagate through all particles.

In the forward configuration shown in FIG. 1C where the granular crystal is driven near the defect, for low driving amplitudes, the actuator excites a periodic (at frequency f_{dr}) vibrational mode localized around the defect. In this case, the energy also does not propagate through the crystal. As the amplitude of the driver is increased, the system jumps from this low amplitude stable periodic solution to a high amplitude stable two-frequency quasiperiodic mode: one frequency is at f_{dr} and the other is at frequency f_{N}. In the nonlinear system shown in FIG. 1C, this results in the distribution of energy to frequencies that are linear combinations of these two frequencies, including energy at low frequencies within the propagating band. Further increase of the driving amplitude induces chaotic vibrations, where the energy is redistributed along broad frequency bands surrounding the peaks of the quasiperiodic state. In both quasiperiodic and chaotic states the energy at low frequencies is transmitted.

The systems shown in FIGS. 1A and 1C may be modeled as a chain of nonlinear oscillators as shown by Eq. 1 below:

$${m}_{n} {\ddot{u}}_{n} = {{A}_{n} [ {Δ}_{n} + {u}_{n - 1} - {u}_{n} ]}_{+}^{3 / 2} - {{A}_{n + 1} [ {Δ}_{n + 1} + {u}_{n} - {u}_{n + 1} ]}_{+}^{3 / 2} - \frac{{m}_{n}}{τ} {\dot{u}}_{n} , \qquad Eq . 1$$

where [Y]₊ denotes the positive part of Y, uₙ is the displacement of the nth sphere around the static equilibrium, mₙ is the mass of the nth particle, and

$${Δ}_{n} = {( \frac{{F}_{0}}{{A}_{n}} )}^{2 / 3}$$

is the static overlap. The contact coefficients

$${A}_{n} = \frac{2 E}{3 ( 1 - {v}^{2} )} {( \frac{{R}_{n - 1} {R}_{n}}{{R}_{n - 1} + {R}_{n}} )}^{1 / 2}$$

are defined by the Hertz law potential between adjacent spheres, where Rₙ is the radius of the nth particle.

Eq. 1 may be linearized by setting τ=∞ which represents the crystal's equilibrium state. The homogenous crystal contains one band of propagating frequencies extending from

$$f = 0 to {f}_{c} = \frac{1}{2 π} \sqrt{\frac{4 {K}_{RR}}{M}} , where {K}_{RR} = \frac{3}{2} {A}_{RR}^{2 / 3} {F}_{0}^{1 / 3}$$

and A_{RR} is the contact coefficient between two large particles. The frequency of the defect mode is calculated by considering a reduced three particle eigensystem, where

$${f}_{d} = \frac{1}{2 π} \sqrt{\frac{\begin{matrix}2 {K}_{Rr} M + {K}_{RR} m + {K}_{Rr} m + \\ \sqrt{- 8 {K}_{Rr} {K}_{RR} mM + {( 2 {K}_{Rr} M + [ {K}_{RR} + {K}_{Rr} ] m )}^{2}}\end{matrix}}{2 nM}} , and$$

$${K}_{Rr} = \frac{3}{2} {A}_{Rr}^{2 / 3} {F}_{0}^{1 / 3}$$

where A_{Rr} is the contact coefficient between a large particle and the defect particle.

Parametric continuation using the Newton-Raphson (NR) method in phase space and numerical integration of Eq. 1 may be used to provide insight into the transition between states occurring in the forward configuration shown in FIG. 1C. Dissipation in the system shown in FIG. 1C is accounted for by using linear damping (a damping coefficient τ=1.75 ms is selected to match experimental results). The actuator boundary is modeled as a moving wall, and the opposite boundary as a free boundary with applied force. Applying NR, a periodic family of solutions as a function of driving amplitude δ is obtained and the linear stability is studied.

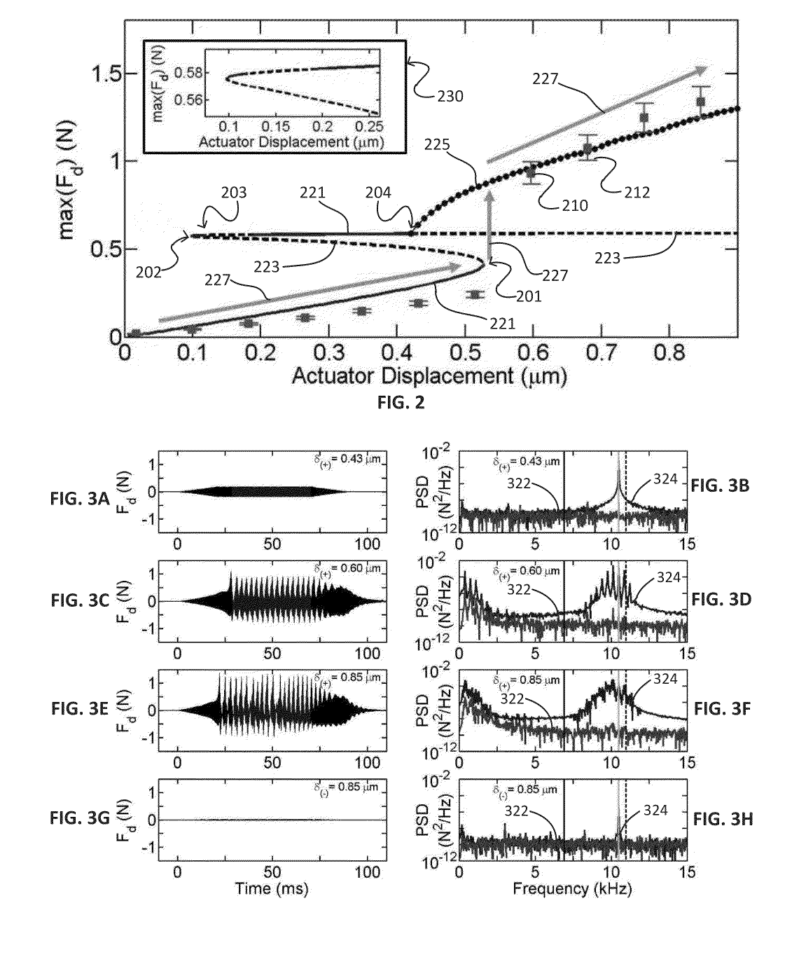

FIG. 2 shows the maximum dynamic force amplitude (four particles from the actuator) for each solution as a function of the driving amplitude (i.e., the actuator displacement) for the granular crystal shown FIG. 1C (with F₀=8 N,∫_{dr}=10.5 kHz, Δ∫=∫_{d} −∫_{dr}≈500 Hz, ∫_{c}=6.9 kHz). The square markers 210 are measured experimental data for the configuration shown in FIG. 1C. Error bars 212 are based on the range of actuator calibration values. The stable periodic solutions in FIG. 2 are denoted with solid lines 221, while the unstable periodic solutions are shown with dashed lines 223. The dotted line 225 corresponds to the numerically calculated quasiperiodic branch described below. The arrows 227 denote the path (and jump) followed with increasing driving amplitude. At turning points 201, 202, stable and unstable periodic solutions collide and mutually annihilate (saddle-center bifurcation). At points 203,204, the periodic solution changes stability and a new two-frequency stable quasiperiodic state emerges. The inset 230 shows the region around points 202 and 203 in greater detail. Because of the demonstrated bifurcation picture, increasing amplitude will result in a progression of the system response following the low amplitude stable periodic solution up to point 201, where the system jumps past the unstable periodic solution to the high amplitude stable quasiperiodic state.

To demonstrate this jump, experiments were performed to harmonically drive the granular crystal of FIGS. 1A and 1C, at frequency f_{dr}=10.5 kHz (with Δf=f_{d}−f_{dr}≈500 Hz, f_{c}=6.9 kHz, F₀=8 N). The driving amplitude was set to δ for 90 ms, except for the first and last 20 ms where the driving amplitude is linearly increased and decreased, respectively. The linear ramp allowed the system to follow the low amplitude stable periodic state (see FIG. 2). The maximum dynamic force measured by the sensors is plotted with the square markers 210 shown in FIG. 2. FIGS. 3A-3H demonstrate each of the states. The dynamic force F_{d} experimentally measured by the sensor 124 four particles from the actuator 110 in FIGS. 1A and 1C is shown in FIGS. 3A, 3C, 3E, 3G. The subscript of the driving amplitude δ denotes the direction, where (+) and (−) are the forward and reverse configurations, respectively. The power spectral densities (PSDs) of the highlighted time region were calculated for both sensors and are shown in FIGS. 3B, 3D, 3F, 3H. Curve 322 corresponds to the sensor 122 at the end of the chain of particles in FIGS. 1A and 1C, and curve 324 corresponds to the sensor 124 four particles from the actuator in FIGS. 1A and 1C.

In the forward configuration, at low driving amplitude (δ₍₊₎=0.43 FIGS. 3A and 3B), a periodic response is observed, with no energy propagating above the noise floor. At higher driving amplitudes (δ₍₊₎=0.60 μm, FIGS. 3C and 3D) a quasiperiodic response is observed with the generation of a second frequency ∫_{N}=10.13 kHz, and the linear combinations of ∫_{N} and ∫_{d}. The combinations within the pass band are transmitted. Increasing the amplitude further (δ₍₊₎=0.85 FIGS. 3E and 3F), a chaotic response is seen, where the area between the frequencies in FIG. 3D, is filled in. By reversing the crystal, even at high amplitudes (δ₍₋₎=0.85 μm, FIGS. 3G and 3H) no transmission is observed, which illustrates the rectification effect. In numerical simulations, a similar behavior is observed within a band of driving frequencies below f_{d}. For the configuration shown FIGS. 1A and 1C and described in relation to FIG. 2, the band of frequencies is approximately 800 Hz wide.

The experimental setup used for the measurements discussed above used stainless steel particles (316 type, with elastic modulus E=193 GPa and Poisson's ratio v=0.3) positioned on two aligned polycarbonate rods. The defect particle (particle 104 in FIGS. 1A and 1C) was aligned with the axis of the crystal using a polycarbonate ring. The piezoelectric actuator was mounted on a steel cube and a soft spring (K_{S}=1.24 kN/m) placed at the other end. The spring and crystal were compressed by positioning a second steel cube with respect to the first. The static load was measured with a load cell placed in between the spring and the steel cube. The displacement of the actuator and embedded strain gage were calibrated optically. The sensors 122, 124 consisted of piezoelectric disks embedded between two halves of a spherical particle, constructed so as to preserve the bulk material properties of the sphere. The output of the sensors 122, 124 was conditioned with voltage amplifiers and analog 30 kHz, 8^{th} order Butterworth low pass filters. The conditioned sensor output was digitally filtered with 300 Hz 5^{th} order Butterworth high pass filters to remove 60 Hz electrical noise.

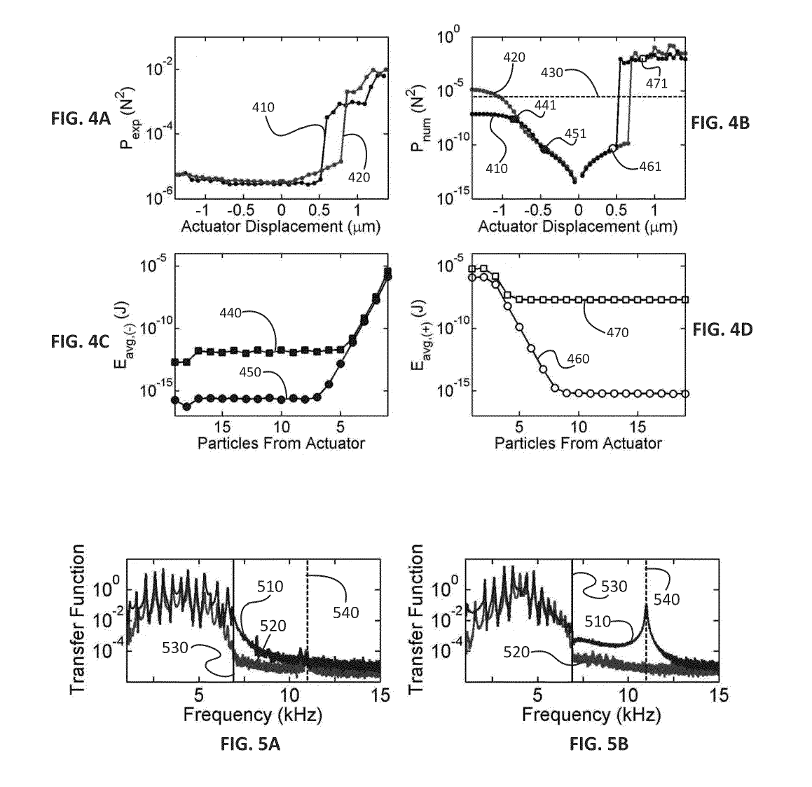

To demonstrate the rectifier tunability with static load, the average transmitted signal power Pₑₓₚ (area under the PSD curves from 0-20 kHz) was measured as a function of actuator displacement, for two different static loads (and driving frequencies). FIGS. 4A-4D show the power transmission and energy distribution. FIG. 4A shows the experimentally measured transmitted power and FIG. 4B shows the numerically calculated average transmitted power. In FIGS. 4A and 4B, curve 410 corresponds to F₀=8.0 N (f_{dr}=10.5 kHz), and the curve 420 is for a static load of F₀=13.9 N (f_{dr}=11.4 kHz, Δf≈550 Hz). In FIG. 4B, line 430 is the experimental noise floor. Positive/negative displacements denote forward/reverse configurations, respectively. For these two configurations the power transmitted is at maximum ˜1.7% of the input power. Changing the static load causes fd to change, which allows the rectifier to operate within a wide range of driving frequencies. In both cases an asymmetric (with respect to directional configuration) energy transmission is observed, with a sharp transition between periodic and quasiperiodic/chaotic states.

Numerical integration of Eq. 1 shows the same qualitative response as in the experiments, as shown by FIG. 4B. In FIG. 4B, the numerically calculated average transmitted power Pₙᵤₘ is plotted for the same configurations as shown in FIG. 4A. Below the experimental noise floor 430, in the reverse configuration, the increasing transmission corresponds to fₛ=f_{dr}/2 subharmonic generation. This phenomenon is generally present at high amplitudes in nonlinear systems, and will result in transmission at sufficiently high driving amplitudes in the reverse configuration (though it could be avoided by using a sufficiently small defect with subharmonic frequency in the gap). To calculate the energy rectification ratio, the time-averaged energy density (per particle site) is plotted as a function of particle number as shown in FIGS. 4C and 4D. FIG. 4C shows E_{avg,(-)} for the reverse configuration and FIG. 4D shows E_{avg,(+)} for the forward configuration. Curve 440 in FIG. 4C corresponds to the numerical run in FIG. 4B at point 441. Curve 450 in FIG. 4C corresponds to the numerical run in FIG. 4B at point 451. Curve 460 in FIG. 4D corresponds to the numerical run in FIG. 4B at point 461. Curve 470 in FIG. 4D corresponds to the numerical run in FIG. 4B at point 471. As shown by curves 440 and 470 in FIGS. 4C and 4D, for high amplitudes, the system decays exponentially down to level of the propagating mode. In both directions as shown by FIGS. 4C and 4D, at low driving amplitude, the system decays exponentially down to the numerical noise floor. In this case, the maximum rectification ratio σ=E_{avg(+)}/E_{avg(-)} for the particle furthest from the actuator is σ≈10⁴, while, because of dissipation and conversion efficiency, the transmitted time-averaged energy density of the last particle is ˜0.35% of the first particle. As described in additional detail below, such rectifiers can be configured as AND and OR logic gates, and the design can be scaled to operate at ultrasonic frequencies for biomedical applications.

In the systems depicted in FIGS. 1A and 1C, the sensors 122, 124 are placed four sites from the actuator 110 and at the end of the crystal. The sensor 124 located four sites away from the actuator 110 is used to measure the localized vibrations within the vicinity of the defect (without being in direct contact with it, so as to avoid affecting its dynamics). The sensor 122 at the end of the crystal is used to measure the transmission through the crystal. In the described rectifier geometry, the bifurcation-based rectification mechanism is only clearly evident with a defect particle 104 placed at a location at two particles away from the actuator 110. For defect particles placed three or more particles away from the actuator, the high attenuation of the signal (with frequency within the band gap) does not allow sufficient energy from the actuator to arrive to the defect particle. For defect particles placed next to the actuator, it has been observed that the effect of the boundary is dominant, and the dynamics of the system becomes more chaotic. The chain length of 19 particles was selected as a balance between having high enough attenuation (arising from the band gap) to demonstrate the rectification effect, and having a small enough dissipation of the signal to maximize the experimental tractability. In numerical simulations, it was observed that decreasing the dissipation in the system can increase the transmission efficiency in the forward configuration.

The linear spectrum of the system shown in FIGS. 1A and 1C was also measured by applying broadband noise via the actuator to the granular crystal statically compressed at F₀=8 N. The transfer functions were calculated by dividing the averaged (over 16 runs) Power Spectral Density (PSD) of the force-time history measured at each sensor, by the mean (over all runs) PSD amplitude in the acoustic band (1 kHz to f_{c}). FIG. 5A shows the experimentally measured PSD transfer function of the reverse configuration shown in FIG. 1A and FIG. 5B shows the PSD transfer function of the forward configuration shown in FIG. 1C. In both FIGS. 5A and 5C, curve 510 is data obtained from the sensor 124 located four particles from the actuator 110 and curve 520 is data obtained from the sensor 122 located 19 particles from the actuator 110. Solid vertical line 530 is the acoustic band upper cutoff frequency f_{c}, and the dashed vertical line 540 is the defect mode frequency f_{d}.

In the reverse configuration, FIG. 5A shows that frequencies above the acoustic cutoff are attenuated. Alternatively, in the forward configuration, the actuator is placed close to the defect and excites the defect mode, as can be seen in the spectrum of the sensor two sites from the defect, as shown by curve 510 in FIG. 5B. The localized nature of this mode is revealed, as this peak is not present at the end of the chain, shown by curve 520 in FIG. 5B. The frequency peak shown in FIG. 5B agrees closely with the analytically predicted defect mode frequency f_{d} (shown by the vertical dashed line 540 in FIG. 5B).

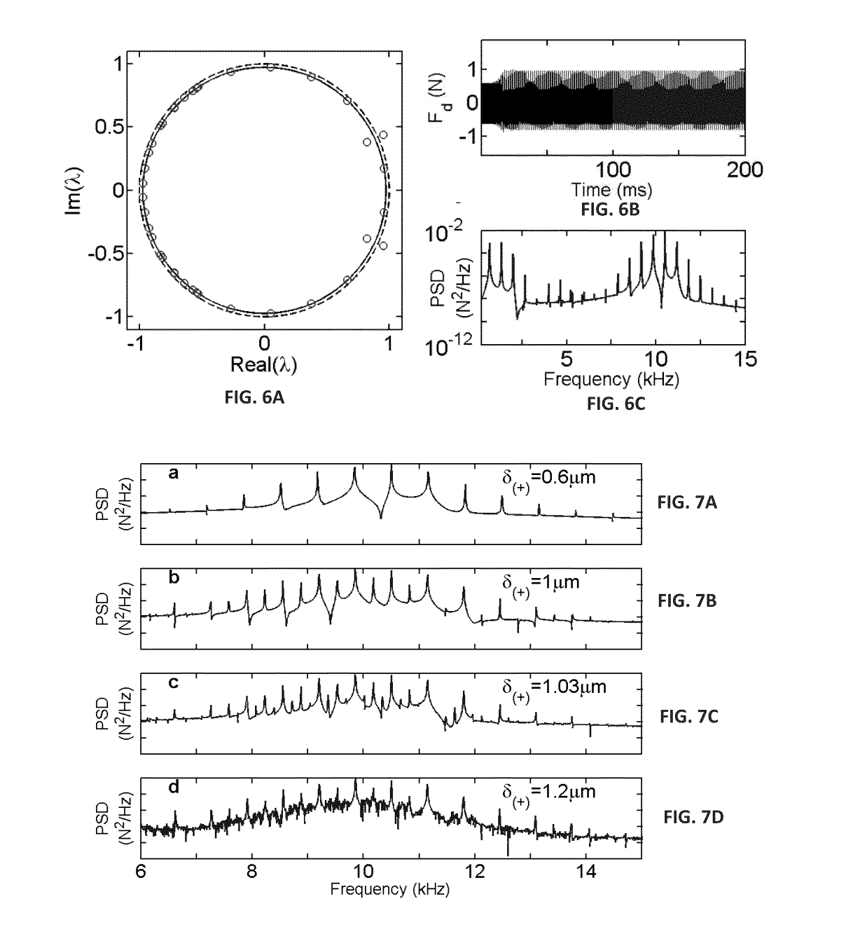

The fundamental mechanism that leads to quasiperiodic vibrations may be explained by applying the Newton's method in phase space to Eq. 1. This method is utilized for obtaining periodic solutions and their Floquet multipliers λⱼ, which can be used to study the linear stability of the solutions. If all |λⱼ|<1, the periodic solution is stable as small perturbations decay exponentially in time. FIG. 6A shows the Floquet spectrum of the periodic solution corresponding to the forward configuration with F₀=8 N, τ=1.75 ms, f_{dr}=10.5 kHz, and δ₍₊₎=0.6 μm. Here all Floquet multipliers lie on a circle of radius

$${e}^{\frac{- 1}{2 π {f}_{dr}}}$$

except four—two which lie outside the unit circle. Because of these two, the periodic solution corresponding to these parameters is linearly unstable. From a bifurcation point of view, this picture is known as a Naimark-Sacker bifurcation. In this case, the unstable periodic solution decays into a stable two-frequency quasiperiodic solution. FIG. 6B shows the time evolution (force-time history of the fourth particle) of the unstable periodic solution of FIG. 6A. The equations of motion from Eq. 1 are integrated using a fourth-order Runge-Kutta scheme with the unstable periodic solution found by Newton's method as the initial condition. After a short transient period, FIG. 6B shows that the unstable periodic solution decays into a stable quasiperiodic solution. FIG. 6C shows multiple frequency peaks based on the linear combinations of two dominant frequencies (f_{dr} and f_{N}), characteristic of a quasiperiodic solution, in the PSD calculated for times 100<t<200 ms, where the frequency peaks corresponding to higher order linear combinations have lower amplitude. Similarly, to obtain the quasiperiodic branch of solutions shown in FIG. 2 above, the dynamic force amplitude is calculated by using the unstable periodic solution of the same driving amplitude as an initial condition for the numerical integrator. To obtain the solutions shown in FIG. 2, integration for 50 ms is used with the maximum amplitude from 40-50 ms.

The transition of the system from quasiperiodic to chaotic dynamics is also explored. Using the same method as described for FIGS. 6A-6C, the PSD of the force-time history (four particles from the actuator) of the time integrated solution is calculated using the unstable periodic solutions found by Newton's method, at increasing amplitudes, as the initial conditions. For the smallest amplitude δ₍₊₎=0.60 μm, FIG. 7A shows a quasiperiodic solution with a discrete set of frequencies based on the linear combinations of f_{dr} and f_{N}. As the amplitude is increased, with δ₍₊₎=1.0 μm as shown in FIG. 7B, the appearance of additional peaks at frequencies based on linear combinations of f_{dr}/2 and f_{N}/2 is observed, which is a sign of double period bifurcation. Increasing the amplitude further with δ₍₊₎=1.03 μm as shown in FIG. 7C, peaks based on f_{dr}/4 and f_{N}/4 are observed(second double period bifurcation). Further increasing the amplitude with δ₍₊₎=1.2 μm as shown in FIG. 7D, a continued cascade of double period bifurcations results in the merging of distinct frequency peaks and the formation of continuous bands.

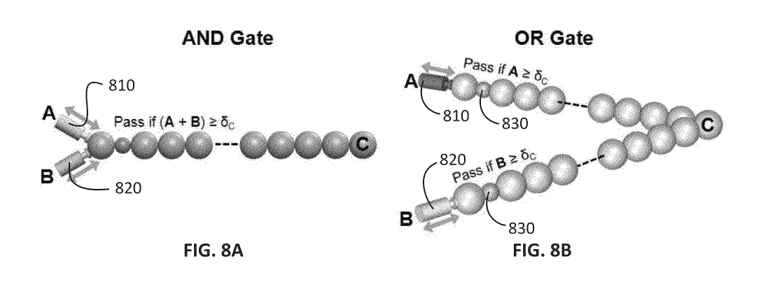

By configuring the tunable frequency mechanical rectifiers to have multiple inputs, tunable frequency logic devices are obtained. At least two types of logic devices may be obtained: the AND gate (shown in FIG. 8A) and the OR gate (shown in FIG. 8B). Assume that the incident harmonic signals from a first source 810 and a second source 820 are in phase. For the AND gate shown in FIG. 8A, a large signal will pass only if the sum of the signals from the first source 810 and the second source 820 are greater than the critical amplitude δ_{c} where the jump phenomenon occurs. Otherwise, if either the first source 810 or second source 820 is off, the signal will be attenuated and not pass. This configuration can also be used in bifurcation based sensors. For instance, if the signal from the first source 810 is set near the critical jump phenomena amplitude, a small deviation in the second source 820 will result in the transmission of a large signal. For the OR gate shown in FIG. 8B, a rectifier 830 (i.e., a defect particle) is placed in each of the branches connected to the first source 810 and the second source 820. If the signal coming from each respective branch is greater than the critical amplitude, this signal will pass and combine with the other signal. Thus a large amplitude signal will pass in all cases except when there is no large signal coming from either the first source 810 or second source 820.

The systems described herein are tunable with changes in static load, and scalable with geometric and material properties. For instance, by reducing the rectifier particle size (i.e., defect particle), assuming F₀=0.1 N and the same configuration and ratio m/M described for FIGS. 1A and 1C, the rectification system has a predicted defect frequency of f_{d}≈1 MHz (characteristic of medical ultrasound) and an overall system length of 6.7 mm. Note also that while the structures described above have 19 particles, rectification systems may also be obtained with fewer than or greater than 19 particles. Rectification systems are also not limited to defect or non-defect particles having the same size, shape, mass, material, or other properties as the defect or non-defect particles described above.

By operating close to the bifurcation point, small perturbations can cause the system's response to switch from the low amplitude non-transmitting state to the high amplitude transmitting state, which is useful for sensing applications. The demonstrated frequency downshifting could also be useful in energy harvesting technologies with frequency dependent absorptivity and emissivity. The flexibility of the system is enhanced by operational frequencies that are tunable with variation of the static load, and with the geometric and material properties. This described method of tunable bifurcation-based mechanical rectification allows for new ways to control the flow of energy.

As described herein, the use of a granular crystal to create a switching and rectification device presents several advantages over other rectification devices. The device is simple and inexpensive in its construction, as it is composed of a one-dimensional array of a small number of elastic particles in contact. Because of the nonlinear potential of the particles in contact, the system is tunable in frequency by adjusting the static load applied to the array. The device is also easily scalable in its geometry to function at a wide ranch of input frequencies. For instance, a system similar to the systems already described herein (audible frequencies) that could function at MHz frequencies would have a total system size on the order of a few millimeters.

The devices, apparatus, methods, arrays, and systems described herein and the underlying bifurcation mechanism have utility in many applications. Devices, as rectifiers and logic gates, may be useful for controlling the propagation of acoustic waves and mechanical vibrations, with applications including: sound proofing, structural vibrations in civil and mechanical applications, and ultrasonic devices. As sensors, these devices may be useful in structural health monitoring, geological sensing (earthquakes), or ultrasonic sensing applications. Furthermore, the underlying bifurcation mechanism may be applied to other discrete/periodic and nonlinear systems for use in optic/photonic and thermal control applications.

The foregoing Detailed Description of exemplary and preferred embodiments is presented for purposes of illustration and disclosure in accordance with the requirements of the law. It is not intended to be exhaustive nor to limit the invention to the precise form or forms described, but only to enable others skilled in the art to understand how the invention may be suited for a particular use or implementation. The possibility of modifications and variations will be apparent to practitioners skilled in the art.

No limitation is intended by the description of exemplary embodiments which may have included tolerances, feature dimensions, specific operating conditions, engineering specifications, or the like, and which may vary between implementations or with changes to the state of the art, and no limitation should be implied therefrom. In particular it is to be understood that the disclosures are not limited to particular compositions or biological systems, which can, of course, vary. This disclosure has been made with respect to the current state of the art, but also contemplates advancements and that adaptations in the future may take into consideration of those advancements, namely in accordance with the then current state of the art. It is intended that the scope of the invention be defined by the Claims as written and equivalents as applicable. It is also to be understood that the terminology used herein is for the purpose of describing particular embodiments only, and is not intended to be limiting. Reference to a claim element in the singular is not intended to mean “one and only one” unless explicitly so stated. As used in this specification and the appended claims, the singular forms “a,” “an,” and “the” include plural referents unless the content clearly dictates otherwise. The term “several” includes two or more referents unless the content clearly dictates otherwise. Unless defined otherwise, all technical and scientific terms used herein have the same meaning as commonly understood by one of ordinary skill in the art to which the disclosure pertains.

Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112, sixth paragraph, unless the element is expressly recited using the phrase “means for . . . ” and no method or process step herein is to be construed under those provisions unless the step, or steps, are expressly recited using the phrase “comprising step(s) for . . . ”

A number of embodiments of the disclosure have been described. Nevertheless, it will be understood that various modifications may be made without departing from the spirit and scope of the present disclosure. Accordingly, other embodiments are within the scope of the following claims.

What is claimed is:

1. A tunable frequency acoustic rectifier comprising a granular crystal, wherein the granular crystal comprises a one-dimensional array of statically compressed particles, wherein the one-dimensional array of particles comprises a plurality of non-defect particles and one defect particle, wherein each non-defect particle has about the same first mass and the defect particle has a second mass, and the second mass is less than the first mass, and wherein the defect particle is located near a boundary of the granular crystal.

2. The tunable frequency acoustic rectifier according to claim 1, wherein the granular crystal has a cutoff frequency and wherein properties of the defect particle in relation to properties of the non-defect particles are chosen to provide a defect frequency greater than the cutoff frequency.

3. The tunable frequency acoustic rectifier according to claim 2, wherein a force statically compressing the granular crystal is equal to F₀ and wherein the cutoff frequency is f_{c}, and wherein
$${f}_{c} = \frac{1}{2 π} \sqrt{\frac{4 {K}_{RR}}{M}} , wherein {K}_{RR} = \frac{3}{2} {A}_{RR}^{2 / 3} {F}_{0}^{1 / 3} ,$$
A_{RR} is a contact coefficient between two non-defect particles, and M is equal to the first mass.

4. The tunable frequency acoustic rectifier according to claim 3, wherein the defect frequency is f_{d}, wherein
$${f}_{d} = \frac{1}{2 π} \sqrt{\frac{\begin{matrix}2 {K}_{Rr} M + {K}_{RR} m + {K}_{Rr} m + \\ \sqrt{- 8 {K}_{Rr} {K}_{RR} mM + {( 2 {K}_{Rr} M + [ {K}_{RR} + {K}_{Rr} ] m )}^{2}}\end{matrix}}{2 nM}}$$
$$wherein$$
$${K}_{Rr} = \frac{3}{2} {A}_{Rr}^{2 / 3} {F}_{0}^{1 / 3} ,$$
A_{Rr} is a contact coefficient between a non-defect particle and the defect particle, m is equal to the second mass, and n is equal to a number of particles in the one-dimensional array of particles.

5. The tunable frequency acoustic rectifier according to claim 2, wherein the granular crystal is configured to receive driving forces at one end of the granular crystal.

6. The tunable frequency acoustic rectifier according to claim 5, wherein the granular crystal comprises one or more particle sensors disposed at particles in the granular crystal located at positions between the defect particle and an end of the granular crystal opposite the end of the granular crystal configured to receive the driving forces.

7. The tunable frequency acoustic rectifier according to claim 1, wherein properties of the defect particle and numbers and properties of the non-defect particles are chosen to suppress propagation of acoustic signals above a cutoff frequency in one linear direction through the granular crystal and to allow propagation of acoustic signals above a specified amplitude in an opposite linear direction through the granular crystal.

8. A method for controlling propagation of mechanical vibrations comprising:
disposing a granular crystal comprising an array of statically compressed contacting particles, wherein at least one particle comprises a light mass defect particle located near a first end of the array of statically compressed contacting particles;
controlling a force used to compress the array of statically compressed contacting particles;
selecting properties of particles in the array of statically compressed contacting particles to obtain a desired cutoff frequency;
selecting properties of the at least one particle comprising a light mass defect particle to obtain a desired defect frequency; and,
configuring the granular crystal to receive a first driving force into the first end of the array of statically compressed contacting particles, whereby mechanical vibrations above the cutoff frequency propagate through the granular crystal when the first driving force is greater than a selected level.

9. The method according to claim 8, wherein the method further comprises:
configuring the granular crystal to receive a second driving force into a second end of the array of statically compressed contacting particles, whereby mechanical vibrations above the cutoff frequency propagate through the granular crystal when the first driving force is greater than a selected level.

10. The method according to claim 9, wherein the force used to compress the array of statically compressed contacting particles is F₀ and the cutoff frequency is f_{c} and wherein selecting properties of particles in the array of statically compressed contacting particles to obtain a desired cutoff frequency comprises:
selecting properties of particles in the array of statically compressed contacting particles to obtain a selected contact coefficient between two particles in the array of statically compressed contacting particles, wherein neither of the two particles comprises a light mass defect particle, and wherein the selected contact coefficient is A_{RR}; and,
selecting properties of particles in the array of statically compressed contacting particles to obtain a selected a mass of each particle in the array of statically compressed contacting particles, and wherein the selected mass is M,
whereby
$${f}_{c} = \frac{1}{2 π} \sqrt{\frac{4 {K}_{RR}}{M}} , and wherein {K}_{RR} = \frac{3}{2} {A}_{RR}^{2 / 3} {F}_{0}^{1 / 3} .$$

11. The method according to claim 10, wherein the defect frequency is f_{d} and wherein the number of particles in the array of statically compressed contacting particles is n and wherein selecting properties of the at least one particle comprising a light mass defect particle to obtain a desired defect frequency comprises:
selecting properties of the at least one particle comprising a light mass defect particle to obtain a selected light mass contact coefficient between the at least one particle comprising a light mass defect particle and another particle in the array of statically compressed contacting particles, and wherein the selected light mass contact coefficient is A_{Rr}; and,
selecting properties of the at least one particle comprising a light mass defect particle to obtain a selected light mass, wherein the selected light mass is m,
whereby
$${f}_{d} = \frac{1}{2 π} \sqrt{\frac{\begin{matrix}2 {K}_{Rr} M + {K}_{RR} m + {K}_{Rr} m + \\ \sqrt{- 8 {K}_{Rr} {K}_{RR} mM + {( 2 {K}_{Rr} M + [ {K}_{RR} + {K}_{Rr} ] m )}^{2}}\end{matrix}}{2 nM}}$$
$$and wherein$$
$${K}_{Rr} = \frac{3}{2} {A}_{Rr}^{2 / 3} {F}_{0}^{1 / 3} .$$

12. The method according to claim 8, wherein selecting properties of particles in the array of statically compressed contacting particles and selecting properties of the at least one particle comprising a light mass defect particle comprise selecting properties to obtain a desired cutoff frequency and a desired defect frequency above one megahertz.

13. The method according to claim 8, wherein particles in the array of statically compressed contacting particles comprise stainless steel particles.

14. A system for controlling mechanical signals comprising:
a first granular crystal comprising a first statically compressed one-dimensional array of contacting particles, wherein the first statically compressed one-dimensional array of contacting particles comprises:
a first plurality of non-defect particles, and
at least one first light mass defect particle, wherein the at least one first light mass defect particle is located near a boundary of the first granular crystal;
a first structure configured for compressing the first statically compressed one-dimensional array of contacting particles to a first desired compressing force; and
a first mechanism for coupling driving forces to the first granular crystal,
wherein the first plurality of non-defect particles are configured to obtain a desired cutoff frequency and the at least one first light mass defect particle is configured to provide a desired defect frequency and wherein the first plurality of non-defect particles and the at least one first light mass defect particle are configured to suppress propagation of mechanical signals above the cutoff frequency in one linear direction through the first granular crystal and to allow propagation of mechanical signals above a specified amplitude in an opposite linear direction through the first granular crystal.

15. The system according to claim 14, wherein the first mechanism for coupling driving forces to the first granular crystal couples driving forces at an end of the first granular crystal closest to the at least one first light mass defect particle located near the boundary of the first granular crystal.

16. The system according to claim 15, wherein the first mechanism for coupling driving forces to the first granular crystal comprises:
a first driving mechanism operating above the cutoff frequency and having a first amplitude, and
a second driving mechanism operating above the cutoff frequency and having a second amplitude,
wherein the first plurality of non-defect particles and the at least one first light mass defect particle are configured to allow propagation of mechanical signals above the specified amplitude in the opposite linear direction through the first granular crystal when the addition of the first amplitude and the second amplitude exceeds the specified amplitude.

17. The system according to claim 15 further comprising:
a second granular crystal comprising a second statically compressed one-dimensional array of contacting particles, wherein the second statically compressed one-dimensional array of contacting particles comprises:
a second plurality of non-defect particles, and
and at least one second light mass defect particle, wherein the at least one second light mass defect particle is located near a boundary of the second granular crystal;
a second structure configured for compressing the second statically compressed one-dimensional array of contacting particles to a desired compressing force; and
a second mechanism for coupling driving forces to the second granular crystal, wherein the second mechanism for coupling driving forces to the second granular crystal couples driving forces at an end of the second granular crystal closest to the at least one second light mass defect particle located near the boundary of the second granular crystal,
wherein an end of the first granular crystal opposite the end of the first granular crystal closest to the at least one first light mass defect particle is mechanically coupled to an end of the second granular crystal opposite the end of the second granular crystal closest to the at least one second light mass defect particle.

18. The system according to claim 14, wherein the first mechanism comprises an actuator.

19. The system according to claim 14, wherein one or more non-defect particles of the first plurality of non-defect particles comprise one or more piezoelectric disks embedded between two halves of the one or more non-defect particles.

20. The system according to claim 19, wherein the one or more piezoelectric disks are electrically coupled to signal conditioning apparatus.
